(19) United States
(12) Patent Application Publication
(10) Pub. No.: US 2022/0164561 A1
(43) Pub. Date: May 26, 2022

(54) DISPLAY APPARATUS

(71) Applicants: Beijing BOE Sensor Technology Co., Ltd., Beijing (CN); BOE Technology Group Co., Ltd., Beijing (CN)

(72) Inventors: Yi DAI, Beijing (CN); Cheng LI, Beijing (CN); Yue GENG, Beijing (CN); Kuiyuan WANG, Beijing (CN); Yajie FENG, Beijing (CN); Zefei LI, Beijing (CN); Chaoyang QI, Beijing (CN); Zhonghuan LI, Beijing (CN)

(73) Assignees: Beijing BOE Sensor Technology Co., Ltd.; BOE Technology Group Co., Ltd.

(21) Appl. No.: 17/354,109

(22) Filed: Jun. 22, 2021

(30) Foreign Application Priority Data
Nov. 25, 2020 (CN) 202011344406.3

(51) Int. Cl. G06K 9/00; H01L 51/00; H01L 27/32; H01L 51/52

(52) U.S. Cl. CPC G06K 9/0004; H01L 51/0097; H01L 27/323; H01L 2251/5338; H01L 27/3244; H01L 51/5275; H01L 51/5284

(57) ABSTRACT

The embodiment of the present disclosure discloses a display apparatus. A flexible optical fingerprint recognition component is obtained by arrangement of a flexible substrate, a flexible fingerprint recognition element and a flexible collimation structure to implement flexible foldable display. In addition, the flexible fingerprint recognition element includes a first flexible fingerprint recognition element and a second flexible fingerprint recognition element which are mutually independent, the first flexible fingerprint recognition element corresponds to a first non-bending area of the flexible display module, the second flexible fingerprint recognition element corresponds to a second non-bending area of the flexible display module, and a non-fingerprint recognition area corresponding to the bending area is provided between the first flexible fingerprint recognition element and the second flexible fingerprint recognition element.

### CROSS REFERENCE TO RELATED APPLICATIONS

The present disclosure claims priority to Chinese Patent Application No. 202011344406.3 filed with the China National Intellectual Property Administration on Nov. 25, 2020, the entire contents of which are incorporated herein by its reference.

### FIELD

The present disclosure relates to the field of fingerprint recognition and particularly relates to a display apparatus.

### BACKGROUND

With more and more mobile phones using OLED screens, under-screen optical fingerprint recognition is gradually replacing rear or front capacitive fingerprint recognition to become the most mainstream fingerprint recognition method.

At present, the folding screen mobile phone is not equipped with a fingerprint recognition element. The first reason is that an ordinary rigid fingerprint recognition element is thicker, generally not less than 400 um, and a middle frame pasting method takes up more space of the phone body, which is not conducive to the lightness and thinness of the mobile phone, and other components cannot easily make up for the segment difference of a fingerprint recognition element; and the second reason is that the rigid fingerprint recognition element cannot be bent, the folding screen is soft, and if the screen is pasted, the downward deformation of the screen will cause the fingerprint recognition element to be peeled off from the screen.

### SUMMARY

A display apparatus provided by the embodiment of the present disclosure includes:

a flexible substrate;

a flexible display module on the flexible substrate; wherein the flexible display module is provided with a first non-bending area, a second non-bending area, and a bending area between the first non-bending area and the second non-bending area;

a flexible fingerprint recognition element between the flexible substrate and the flexible display module, wherein the flexible fingerprint recognition element includes a first flexible fingerprint recognition element and a second flexible fingerprint recognition element which are mutually independent, the first flexible fingerprint recognition element corresponds to the first non-bending area, the second flexible fingerprint recognition element corresponds to the second non-bending area, and a non-fingerprint recognition area corresponding to the bending area is provided between the first flexible fingerprint recognition element and the second flexible fingerprint recognition element; and

a flexible collimation structure between the flexible fingerprint recognition element and the flexible display module, wherein the flexible collimation structure is configured to make light rays form collimation light rays to enter the flexible fingerprint recognition element.

Optionally, in the display apparatus provided by the embodiment of the present disclosure, the non-fingerprint recognition area is not provided with a pattern of a fingerprint recognition element.

Optionally, in the display apparatus provided by the embodiment of the present disclosure, the first flexible fingerprint recognition element includes: an array of first thin film transistors between the flexible substrate and the flexible display module, and an array of first light sensing devices connected with the array of first thin film transistors; the second flexible fingerprint recognition element includes: an array of second thin film transistors between the flexible substrate and the flexible display module, and a second array of second light sensing devices connected with the array of second thin film transistors; and

both the first light sensing devices and the second light sensing devices are configured to convert a light signal carrying fingerprint information to an electric signal, and both the first thin film transistors and the second thin film transistors are configured to output the corresponding electric signal to a processing circuit for fingerprint recognition.

Optionally, the display apparatus provided by the embodiment of the present disclosure further includes: a first gate driving circuit, a second gate driving circuit, a first source driving circuit and a second source driving circuit, wherein

the first gate driving circuit is electrically connected with gates of the first thin film transistors, the first source driving circuit is electrically connected with sources of the first thin film transistors, and drains of the respective first thin film transistors is electrically connected with the respective first light sensing devices; and

the second gate driving circuit is electrically connected with gates of the second thin film transistors, the second source driving circuit is electrically connected with sources of the second thin film transistors, and drains of the respective second thin film transistors is electrically connected with the respective second light sensing devices.

Optionally, in the display apparatus provided by the embodiment of the present disclosure, the flexible collimation structure includes: a light shielding layer between the flexible fingerprint recognition element and the flexible display module, and an array of micro-lenses between the light shielding layer and the flexible display module; and

the light shielding layer is provided with a light shielding portion and a plurality of via holes in the light shielding portion, an orthographic projection of the via holes on the flexible substrate has an overlapped area with an orthographic projection of the light sensing devices on the flexible substrate, and the via holes are covered by the micro-lenses.

Optionally, in the display apparatus provided by the embodiment of the present disclosure, an orthographic projection of the flexible collimation structure on the flexible substrate covers an orthographic projection of the bending area, the first non-bending area and the second non-bending area on the flexible substrate.

Optionally, the display apparatus provided by the embodiment of the present disclosure further includes an infrared light filter layer between the flexible fingerprint recognition element and the flexible collimation structure, wherein the infrared light filter layer is configured to prevent infrared light from entering the flexible fingerprint recognition element.

Optionally, in the display apparatus provided by the embodiment of the present disclosure, an orthographic projection of the infrared light filter layer on the flexible substrate covers an orthographic projection of the bending area, the first non-bending area and the second non-bending area on the flexible substrate.

Optionally, the display apparatus provided by the embodiment of the present disclosure further includes a blocking layer between the flexible substrate and the flexible fingerprint recognition element, wherein the blocking layer is made of SiNx or a combination of SiNx and SiO2.

Optionally, in the display apparatus provided by the embodiment of the present disclosure, the flexible substrate is made of polyimide, and a thickness of the flexible substrate is 15 μm to 30 μm.

Optionally, in the display apparatus provided by the embodiment of the present disclosure, the flexible collimation structure and the flexible display module are fitted with each other by an optical clear adhesive.

Optionally, the display apparatus provided by the embodiment of the present disclosure further includes a cover plate which is on a side, facing away from the flexible substrate, of the flexible display module, wherein the cover plate is a flexible cover plate.

The beneficial effects of the embodiment of the present disclosure are as follows.

The embodiment of the present disclosure provides a display apparatus. Through arrangement of a flexible substrate, a flexible fingerprint recognition element and a flexible collimation structure, a flexible optical fingerprint recognition component is obtained and may be applied to implementing flexible foldable display. In addition, the flexible fingerprint recognition element includes a first flexible fingerprint recognition element and a second flexible fingerprint recognition element which are independent, the first flexible fingerprint recognition element corresponds to the first non-bending area of the flexible display module, the second flexible fingerprint recognition element corresponds to the second non-bending area of the flexible display module, and a non-fingerprint recognition area corresponding to the bending area is provided between the first flexible fingerprint recognition element and the second flexible fingerprint recognition element; and in other words, the non-fingerprint recognition area does not have a fingerprint recognition function, and areas in which the first flexible fingerprint recognition element and the second flexible fingerprint recognition element are located respectively correspond to the two non-bending areas of the flexible display module, so that a multi-finger fingerprint recognition function may be realized and safety in fingerprint use scenarios may be enhanced.

### BRIEF DESCRIPTION OF THE DRAWINGS

FIG. 1 is a schematic cross-sectional view of a display apparatus provided by an embodiment of the present disclosure.

FIG. 2 is a stereoscopic schematic diagram of a part of structures in FIG. 1 provided by an embodiment of the present disclosure.

FIG. 3 is a schematic diagram of pixel layout of a flexible fingerprint recognition element in FIG. 1 provided by an embodiment of the present disclosure.

FIG. 4A to FIG. 4D are schematic diagrams of screen pressing fingerprints corresponding to a flexible substrate and a rigid substrate respectively provided by an embodiment of the present disclosure.

FIG. 5 is a schematic cross-section diagram of a fingerprint recognition element corresponding to a rigid substrate provided by an embodiment of the present disclosure.

FIG. 6 is a schematic diagram of fingerprint functions under folding of a folding screen corresponding to FIG. 1 provided by an embodiment of the present disclosure.

### DETAILED DESCRIPTION OF THE EMBODIMENTS

In order to make the objectives, technical solutions and advantages of embodiments of the present disclosure clearer, the technical solutions of the embodiments of the present disclosure will be described clearly and completely below with reference to the drawings of the embodiments of the present disclosure. Obviously, the described embodiments are some embodiments of the present disclosure, but not all embodiments. In addition, the embodiments of the present disclosure and the features in the embodiments may be combined with each other without conflict. Based on the described embodiments of the present disclosure, all other embodiments obtained by those of ordinary skill in the art without creative labor belong to the scope of protection of the present disclosure.

Unless otherwise defined, the technical terms or scientific terms used in the present disclosure shall have the general meaning understood by those with general skills in the field to which the present disclosure belongs. As used in the present disclosure, similar words such as “comprise” or “include” mean that the elements or objects appearing before the word cover the listed elements or objects appearing after the word and their equivalents, and other elements or objects are not excluded. Similar words such as “connect” or “couple” are not limited to physical or mechanical connection, but may include electrical connection, whether direct or indirect. “Inner”, “outer”, “upper”, “lower” and so on are only used to express the relative positional relationship. If the absolute position of a described object is changed, the relative positional relationship may change accordingly.

It should be noted that the size and shape of each figure in the drawings do not reflect the true scale, and the purpose is only to schematically illustrate the content of the present disclosure. In addition, the same or similar reference numerals refer to the same or similar elements or elements having the same or similar functions throughout.

Under-screen optical fingerprint recognition has the advantages of high recognition rate, fast recognition speed and no influence on the appearance of mobile phones. At present, under-screen optical fingerprint recognition is applied under OLED display screens, which mainly adopts a camera-imaging single-point fingerprint recognition apparatus and is suitable for glass-based hard screen fingerprint recognition. The main structure of a fingerprint recognition apparatus with a fingerprint camera under the screen includes: cover glass, an OLED display screen and light sensors composed of camera CMOSs. The under-screen optical fingerprint recognition principle is: an OLED is used as a light source to emit light to fingers, and the reflection intensity of fingerprint valleys/ridges to light is different, which leads to different light intensities to an optical sensor panel, and different electric signals are generated by different light intensities, so the fingerprint lines may be distinguished by the difference of the electric signals. However, using camera CMOS imaging technology may only realize single-point fingerprint recognition, but cannot realize multi-point and large-area fingerprint recognition.

At present, with the continuous development of full screens, more and more forms of mobile phones are applied to life, such as waterdrop screens, digging screens, etc. Among them, folding screen mobile phones will become one of the mainstream mobile phone forms in the future because of their larger screens, richer display content and better use experience for people. Because of its special usage, the internal structure of the folding screen mobile phones is quite different from that of ordinary mobile phones, such as folding the screens through hinge structures, or the screens cannot use ordinary glass cover plates, etc.

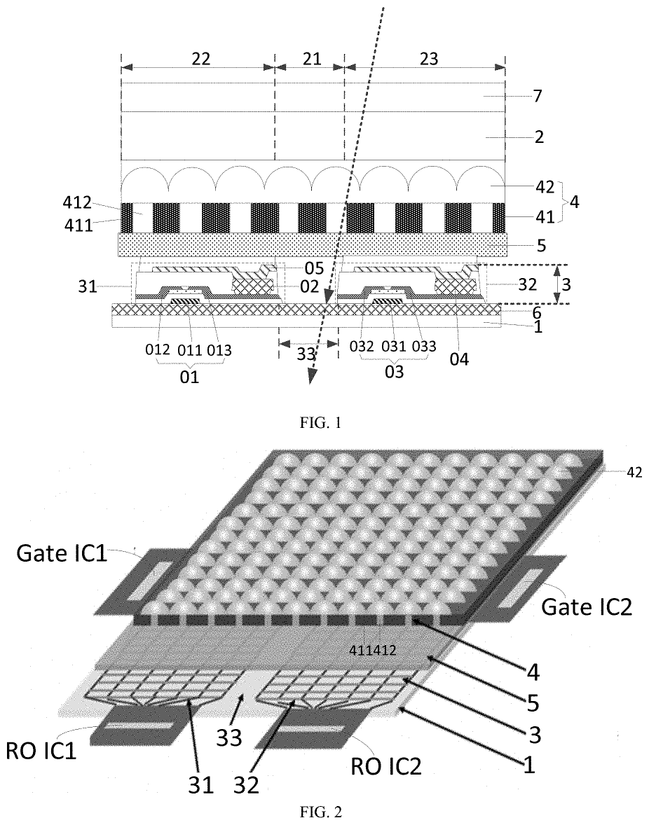

The embodiment of the present disclosure provides a display apparatus, as shown in FIG. 1 and FIG. 2. FIG. 1 is a schematic cross-sectional view of the display apparatus. FIG. 2 is a stereoscopic schematic diagram of a part of film layers in FIG. 1. The display apparatus includes:

a flexible substrate 1;

a flexible display module 2 on the flexible substrate 1, wherein the flexible display module 2 is provided with a first non-bending area 22, a second non-bending area 23, and a bending area 21 between the first non-bending area 22 and the second non-bending area 23 on;

a flexible fingerprint recognition element 3 between the flexible substrate 1 and the flexible display module 2, wherein the flexible fingerprint recognition element 3 includes a first flexible fingerprint recognition element 31 and a second flexible fingerprint recognition element 32 which are mutually independent, the first flexible fingerprint recognition element 31 corresponds to the first non-bending area 22, the second flexible fingerprint recognition element 32 corresponds to the second non-bending area 23, and a non-fingerprint recognition area 33 corresponding to the bending area 21 is provided between the first flexible fingerprint recognition element 31 and the second flexible fingerprint recognition element 32; and

a flexible collimation structure 4 between the flexible fingerprint recognition element and the flexible display module, wherein the flexible collimation structure 4 is configured to make light rays form collimation light rays to enter the flexible fingerprint recognition element 3.

The display apparatus provided by the embodiments of the present disclosure provides is provided with the flexible optical fingerprint recognition component through arrangement of the flexible substrate 1, the flexible fingerprint recognition element 3 and the flexible collimation structure 4 to implement flexible foldable display. In addition, the flexible fingerprint recognition element 3 includes the first flexible fingerprint recognition element 31 and the second flexible fingerprint recognition element 32 which are mutually independent, the first flexible fingerprint recognition element 31 corresponds to the first non-bending area 22 of the flexible display module 2, the second flexible fingerprint recognition element 32 corresponds to the second non-bending area 23 of the flexible display module 2, and the non-fingerprint recognition area 33 corresponding to the bending area 21 is provided between the first flexible fingerprint recognition element 31 and the second flexible fingerprint recognition element 32. In other words, the non-fingerprint recognition area 33 is not provided with a fingerprint recognition function, and areas in which the first flexible fingerprint recognition element 31 and the second flexible fingerprint recognition element 32 are located respectively correspond to the two non-bending areas 22 and 23 of the flexible display module 2, so that a multi-finger fingerprint recognition function may be realized and safety in fingerprint use scenarios may be enhanced.

In some embodiments, as shown in FIG. 1, the flexible display module 2 may be a self-luminescence display screen which takes a self-luminescence unit as a display pixel, such as an OLED display screen or an LED display screen. Thus, the display screen may act as an excitation light source, e.g., emits excitation light to a user's finger, and then the excitation light is reflected by the finger to form a target light signal. Of course, the flexible display module 2 may be an LCD display screen or other driven luminescence display screens, which is not limited by the embodiments of the present disclosure. When the flexible display module 2 is a driven luminescence display screen, the display apparatus may be provided with a backlight source under the display screen. As an excitation light source, the backlight source emits excitation light to the user's finger, and then the excitation light is reflected by the finger to form the target light signal.

The embodiments of the present disclosure take the example that the flexible display module 2 shown in FIG. 1 is an OLED display screen.

In some embodiments, in the display apparatus provided by the embodiments of the present disclosure, as shown in FIG. 1 and FIG. 2, the non-fingerprint recognition area 33 is not provided with the pattern of the fingerprint recognition element. In other words, when the flexible fingerprint recognition element 3 is prepared on the flexible substrate 1, no Array process is performed in the non-fingerprint recognition area 33 in the Array processing stage, namely the non-fingerprint recognition area 33 is an empty area and is applied under the foldable bending area 21 of the flexible display module 2. No Array process is performed in the non-fingerprint recognition area 33, so that breaking and crushing of a non-mental layer (inorganic layer) caused by screen bending may be prevented.

In some embodiments, in the display apparatus provided by the embodiments of the present disclosure, as shown in FIG. 2, the first flexible fingerprint recognition element 31 includes: an array of first thin film transistors 01 between the flexible substrate 1 and the flexible display module 2, and an array of first light sensing devices 02 connected with the array of first thin film transistors 01; and the second flexible fingerprint recognition element 32 includes: an array of second thin film transistors 03 between the flexible substrate 1 and the flexible display module 2, and an array of second light sensing devices 04 connected with the array of second thin film transistors 03.

Both the first light sensing devices 02 and the second light sensing devices 04 are configured to convert a light signal carrying fingerprint information to an electric signal, and both the first thin film transistors 01 and the second thin film transistors 03 are configured to output the corresponding electric signal to a processing circuit (not shown in figures) for fingerprint recognition.

In the embodiments of the present disclosure, the flexible fingerprint recognition element 3 may be prepared by a TFT-LCD process, and may cooperate with the flexible collimation structure 4 to realize flexible foldable display. The array of thin film transistors and the array of light sensing devices of the flexible fingerprint recognition element 3 may be prepared with large areas, so that multi-point and large-area fingerprint recognition may be realized under cooperation with the large-area flexible substrate 1.

In some embodiments, both the array of first light sensing devices 02 and the array of second light sensing devices 04 include a plurality of light sensing devices in array arrangement, and both the array of first thin film transistors 01 and the array of second thin film transistors 03 include a plurality of thin film transistors in array arrangement. The plurality of first light sensing devices 02 in the array of first light sensing devices 02 are in one-to-one correspondence to the plurality of first thin film transistors 01 in the array of first thin film transistors 01, and the plurality of second light sensing devices 04 in the array of second light sensing devices 04 are in one-to-one correspondence to the plurality of second thin film transistors 03 in the array of second thin film transistor 03.

In some embodiments, the first light sensing devices 02 and the second light sensing devices 04 may be photodiodes. In some embodiments, the photodiodes may include organic photodiodes or inorganic photodiodes.

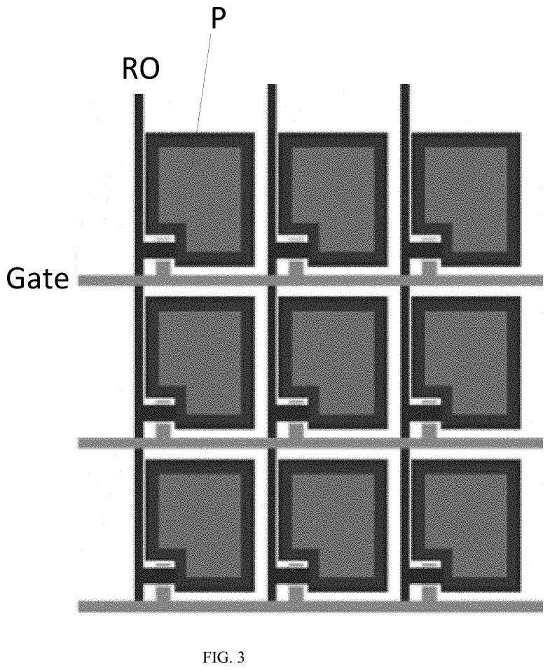

As shown in FIG. 3, which is a schematic diagram of a pixel structure of an area in which the first flexible fingerprint recognition element 31 in FIG. 1 is located, one pixel P is formed by each first thin film transistor 01 and the first light sensing device 02 correspondingly connected with it, a gate of the first thin film transistor 01 is connected with a gate line Gate, a drain of the first thin film transistor 01 is connected with the first light sensing device 02, and a source of the first thin film transistor 01 is connected with a reading line RO.

In some embodiments, the display apparatus provided by the embodiments of the present disclosure, as shown in FIG. 1 to FIG. 3, further includes: a first gate driving circuit Gate IC1, a second gate driving circuit Gate IC2, a first source driving circuit RO IC1 and a second source driving circuit RO IC2.

The first gate driving circuit Gate IC1 is electrically connected with gates 011 of the first thin film transistors 01, the first source driving circuit RO IC1 is electrically connected with sources 012 of the first thin film transistors 01, and a drain 013 of the first thin film transistor 01 is electrically connected with the first light sensing device 02 corresponding to the first thin film transistor 01.

The second gate driving circuit Gate IC 2 is electrically connected with gates 031 of the second thin film transistors 03, the second source driving circuit RO IC2 is electrically connected with sources 032 of the second thin film transistors 03, and a drain 033 of the second thin film transistor 03 is electrically connected with the second light sensing device 01 corresponding to the second thin film transistor 03.

In some embodiments, as shown in FIG. 1, the first flexible fingerprint recognition element 31 further includes an electrode 05 electrically connected with the first light sensing device 02, and the second flexible fingerprint recognition element 32 further includes another electrode 05 electrically connected with the second light sensing device 04.

In the display apparatus provided by the embodiments of the present disclosure, the first flexible fingerprint recognition element 31 and the second flexible fingerprint recognition element 32 correspond to their own Gate ICs and RO ICs, respectively, the gate line (scanning line) of a pixel array is controlled by one Gate IC, the source line (scanning line) of the pixel array is controlled by one ROIC (reading IC), and the non-fingerprint recognition area 33 is provided with no circuit, so that the problem of breaking of a non-metal layer (inorganic layer) under folding of the display apparatus may be prevented, and reliability of the display apparatus may be enhanced.

In some embodiments, in the display apparatus provided by the embodiments of the present disclosure, as shown in FIG. 1 and FIG. 2, the flexible collimation structure 4 includes: a light shielding layer 41 between the flexible fingerprint recognition element 3 and the flexible display module 2, and an array of micro-lenses 42 between the light shielding layer 41 and the flexible display module 2.

The light shielding layer 41 is provided with a light shielding portion 411 and a plurality of via holes 412 in the light shielding portion 411, an orthographic projection of the via holes 412 on the flexible substrate 1 has an overlapped area with an orthographic projection of the light sensing devices (02 and 04) on the flexible substrate 1, and the via holes 412 are covered by the micro-lenses 42.

In some embodiments, as shown in FIG. 1 and FIG. 2, light focused by the micro-lenses 42 may pass through the via holes 412 and is then received by the light sensing devices (02 and 04), the received light signal carrying fingerprint information is converted to the electric signal by the light sensing devices (02 and 04), so that fingerprint recognition is realized. In some embodiments, the via holes 412 and the micro-lenses 42 may be disposed in one-to-one correspondence.

In some embodiments, the light signal focused by the micro-lenses 42 may reach the light sensing devices (02 and 04) only after passing through the via holes 412 in the light shielding layer 41 below. The flexible collimation structure 4 may screen out light rays reflected by the finger in a nearly collimated manner, so that the light rays may reach the light sensing devices (02 and 04) below. The light sensing devices (02 and 04) may detect and read intensities of the light rays. The energy of downward transmission light from valleys of the fingerprint is different from the energy of downward transmission light from ridges of the fingerprint, so that the intensities of the light rays detected by the light sensing devices (02 and 04) are different. In this way, the fingerprint information is acquired, and large-area fingerprint recognition is realized. In addition, the light shielding portion 411 may be used to prevent crosstalk between light rays from different through holes 412, so that accuracy of fingerprint information recognized is enhanced.

In some embodiments, the light shielding layer may be made of metal.

The optical fingerprint recognition component constituted by the flexible fingerprint recognition element, the infrared light filter layer and the flexible collimation structure provided by the embodiments of the present disclosure may convert the light signal into the electric signal. When disposed under a display screen, the optical fingerprint recognition component is used for receiving target signal light reflected by, for example, the finger above the display screen. In addition, the target signal light may be converted to the electric signal, so that a fingerprint image may be generated. The optical fingerprint recognition component may further provide the fingerprint image to the processing circuit (image processor) for image processing, so that a fingerprint signal may be obtained. In addition, the fingerprint signal may be identified by an algorithm.

In some embodiments, in the display apparatus provided by the embodiments of the present disclosure, as shown in FIG. 1 and FIG. 2, an orthographic projection of the flexible collimation structure 4 on the flexible substrate 1 covers orthographic projections of the bending area 21, the first non-bending area 22 and the second non-bending area 23 on the flexible substrate 1. In some embodiments, the non-fingerprint recognition area 33 is provided with no circuit, but the flexible collimation structure 4 still needs to cover the bending area 21 (corresponding to the non-fingerprint recognition area 33). In this way, the segment differences and chromatic aberrations between the non-fingerprint recognition area 33 and the fingerprint recognition functional areas in which the first flexible fingerprint recognition element 31 and the second flexible fingerprint recognition element 32 are located may be prevented, and thus the diversity observed from the front of a screen may be avoided.

In some embodiments, in order to increase the image signal-to-noise ratio and filter light in the spectral range not needed by fingerprint imaging, the display apparatus provided by the embodiments of the present disclosure, as shown in FIG. 1 and FIG. 2 further includes an infrared light filter layer 5 between the flexible fingerprint recognition element 3 and the flexible collimation structure 4, wherein the infrared light filter layer 5 is configured to prevent infrared light from entering the flexible fingerprint recognition element 3. In some embodiments, the infrared light in light rays, a part of red light and invisible UV light may be filtered by the infrared light filter layer 5, so that influences of environmental high-intensity light signals on the light sensing devices may be reduced, and the performance of resisting the high-intensity light may be enhanced.

In some embodiments, in the display apparatus provided by the embodiments of the present disclosure, as shown in FIG. 1 and FIG. 2, the orthographic projection of the infrared light filter layer 5 on the flexible substrate 1 covers the orthographic projections of the bending area 21, the first non-bending area 22 and the second non-bending area 23 on the flexible substrate 1. In this way, the segment differences and chromatic aberrations between the non-fingerprint recognition area 33 and the fingerprint recognition functional areas in which the first flexible fingerprint recognition element 31 and the second flexible fingerprint recognition element 32 are located may be further prevented, and thus the diversity observed from the front face of a screen may be avoided further.

As shown in FIG. 1 and FIG. 2, the flexible fingerprint recognition element 3 may be prepared by a TFT+PIN (photodiode) process, In some embodiments including the following steps.

Firstly, the flexible substrate (such as PI) is cleared and water vapor on surfaces of the flexible substrate is dried, and stains on the surfaces of the flexible substrate are removed. The selected PI may be prepared by coating glass with liquid PI, or a PI film may be directly hot-pressed on a surface of the glass by a silane coupling agent.

Then, a blocking layer 6 is formed between the flexible substrate 1 and the flexible fingerprint recognition element 3, wherein the blocking layer 6 is made of SiNx or a combination of SiNx and SiO2. The arrangement of the blocking layer 6 has the following advantages: firstly, it blocks water and oxygen, and prevents water and oxygen from penetrating from the back of PI to damage the elements and the optical film after the fingerprint recognition element is peeled off; secondly, SiNx or SiNx+SiO2 is more conducive to the subsequent deposition of the gate film layer of TFT; and thirdly, by adjusting the process conditions of SiNx or the ratio of SiNx/SiO2, the stress of the film for blocking water-oxygen changes and may offset the stress of the subsequent film to avoid stress accumulation and to prevent the film layer from breaking due to excessive stress and spontaneous curling of the flexible fingerprint recognition element which has been peeled off from the glass.

Then, an array of thin film transistors and an array of light sensing devices in the flexible fingerprint recognition element are prepared. Starting from the gate, the TFT+PIN process and structure are the same as those of the rigid device, and the gate, the gate insulation layer, the source and drain, a photosensitive layer, a flat layer, etc., are successively deposited. FIG. 3 is a schematic plan view of 3*3 pixels in the flexible fingerprint recognition element provided by the embodiments of the present disclosure. The gate, the source and the drain constitute a TFT of the pixel, and the drain of the TFT serves as one electrode of the photodiode with the PIN junction and is connected with the cathode of the photodiode.

Finally, after the Array process is completed on the flexible fingerprint recognition element, the optical fingerprint recognition component composed of the flexible fingerprint recognition element, the infrared light filter layer and the flexible collimation structure is finally obtained by cutting, Bonding IC, fitting the infrared light filter layer and the flexible collimation structure, peeling and other module processes.

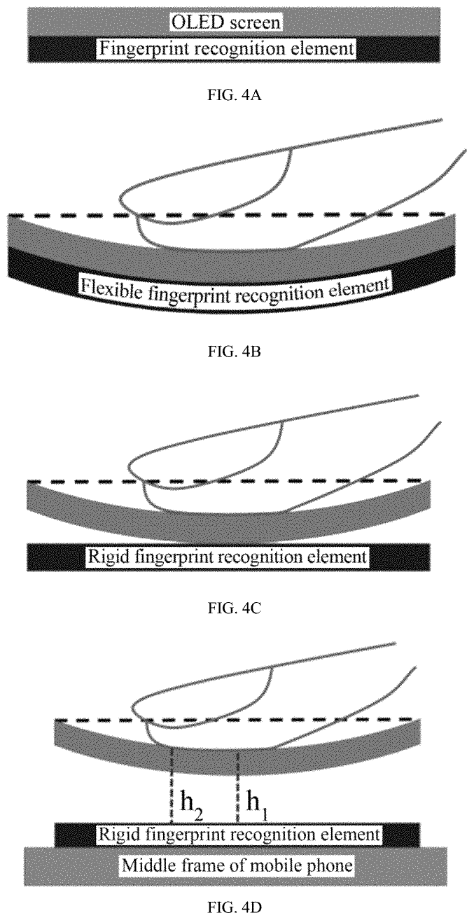

In some embodiments, after all the processes are completed, the optical fingerprint recognition component may be attached to the back of the screen by an optical clear adhesive, as shown in FIG. 4A, and the fingerprint recognition function may be realized by matching with appropriate circuit components and algorithms. As shown in FIG. 4B, during pressing by the finger, the screen is deformed to a certain extent, and the flexible fingerprint recognition element may bend along with the deformation of the screen. The distance between the screen and the flexible fingerprint recognition element remains unchanged, so that the phenomenon that the signal in the center area of the fingerprint has a high intensity and the signal in the edge area of the fingerprint is low may be avoided when the fingerprint image is taken. For a rigid fingerprint recognition element, if the screen fitting method is adopted, as shown in FIG. 4C, the screen is deformed, the fingerprint recognition element cannot be bent, and the edge of the fingerprint recognition element will be peeled off from the screen; if the middle frame fitting method is adopted by the mobile phone, the fingerprint recognition element occupies a large space of the body of the mobile phone. As shown in FIG. 4D, the signal in the center area of the fingerprint close to the fingerprint recognition element has a high intensity, and the signal in the edge of the fingerprint far from the fingerprint recognition element has a low intensity which is not conducive to collecting more fingerprint feature points. The distance h2 between the edge of the fingerprint and the rigid fingerprint recognition element is greater than the distance h1 between the center area of the fingerprint and the rigid fingerprint recognition element. Therefore, the fingerprint recognition component provided by the embodiments of the present disclosure may be placed under the screen in the screen fitting method, and may be deformed along with the screen when pressed because of its soft property, so that the distance between the fingerprint and the fingerprint sensor is the same, and the phenomenon that the signal in the center area of the finger has a high intensity and the signal in the edge area has a low intensity may be avoided.

In some embodiments, in the display apparatus provided by the embodiments of the present disclosure, as shown in FIG. 1 and FIG. 2, the flexible substrate 1 may be made of polyimide, of course, the flexible substrate 1 may be made of other polymer materials; and a thickness of the flexible substrate may be 15 μm to 30 μm.

In some embodiments, in the display apparatus provided by the embodiments of the present disclosure, as shown in FIG. 1 and FIG. 2, the flexible collimation structure 4 and the flexible display module 2 may be fitted with each other by an optical clear adhesive (OCA).

In some embodiments, the display apparatus provided by the embodiments of the present disclosure further includes, as shown in FIG. 1, a cover plate 7 on a side, facing away from the flexible substrate 1, of the flexible display module 2, wherein the cover plate 7 is a flexible cover plate.

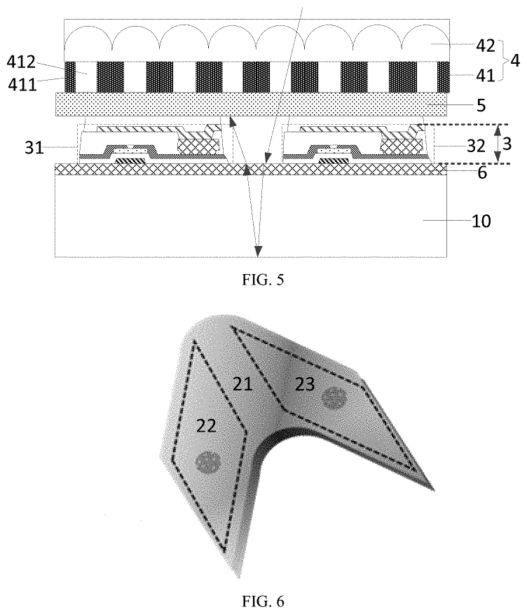

As shown in FIG. 1 and FIG. 5, FIG. 5 shows a fingerprint recognition component using a rigid substrate 10 (e.g., a glass substrate). When light irradiates the rigid substrate through the via holes 412, the incident light irradiating on the flexible substrate 1 in FIG. 1 is different from that on the rigid substrate 10 in FIG. 5. Since the flexible substrate 1 in FIG. 1 is relatively thin, generally 15 μm to 30 μm, and light rays (indicated by dashed arrows) may substantially directly pass through it. As for the rigid substrate 10 in FIG. 5, the thickness is generally 500 μm, the incident light (indicated by the straight arrows) may be reflected by the lower surface of the rigid substrate 10 to irradiate the lower surface of the flexible collimation structure 4, and the flexible collimation structure 4 may continue to reflect the light to the light sensing device to cause crosstalk between light rays. Therefore, the fingerprint recognition component with the flexible substrate 1 provided by the embodiments of the present disclosure may not only realize large-area fingerprint recognition on the folding screen, but may also avoid crosstalk between light rays. In addition, the flexible fingerprint recognition element is lighter and thinner than the rigid substrate structure, and is expected to be about 200 μm thinner than the rigid substrate fingerprint recognition element, thus greatly saving the space in the mobile phone.

As shown in FIG. 6, a large-area flexible fingerprint recognition element is matched with a folding screen mobile phone, so that the unlocking area of the folding screen mobile phone is larger, and unlocking in any area of a half screen or a full screen may be realized. Compared with the silicon-based single-finger unlocking scheme in the related art, the large-area flexible fingerprint recognition element may further realize multi-finger unlocking with higher safety.

In some embodiments, the display apparatus provided by the embodiments of the present disclosure may be any product or component with a display function, such as a mobile phone, a tablet computer, a television, a display, a notebook computer, a digital photo frame, a navigator, etc. Existence of other essential components of the display apparatus should be understood by those of ordinary skill in the art, and will not be described in detail here, nor should it be taken as a limitation of the present disclosure.

The display apparatus provided by the embodiments of the present disclosure is provided with the flexible optical fingerprint recognition component through configuration of the flexible substrate, the flexible fingerprint recognition element and the flexible collimation structure to implement flexible foldable display. In addition, the flexible fingerprint recognition element includes the first flexible fingerprint recognition element and the second flexible fingerprint recognition element which are mutually independent, the first flexible fingerprint recognition element corresponds to the first non-bending area of the flexible display module, the second flexible fingerprint recognition element corresponds to the second non-bending area of the flexible display module, and the non-fingerprint recognition area corresponding to the bending area is provided between the first flexible fingerprint recognition element and the second flexible fingerprint recognition element. In other words, the non-fingerprint recognition area is not provided with a fingerprint recognition function, and areas in which the first flexible fingerprint recognition element and the second flexible fingerprint recognition element are located respectively correspond to the two non-bending areas of the flexible display module, so that a multi-finger fingerprint recognition function may be realized and safety in fingerprint use scenarios may be enhanced.

Although the preferred embodiments of the present disclosure have been described, those skilled in the art may make additional changes and modifications to these embodiments once they know the basic inventive concepts. Therefore, the appended claims are intended to be interpreted as including the preferred embodiments and all changes and modifications falling within the scope of the present disclosure.

Obviously, those skilled in the art may make various modifications and variations to the embodiments of the present disclosure without departing from the spirit and scope of the embodiments of the present disclosure. In this way, if these modifications and variations of the embodiments of the present disclosure fall within the scope of the claims and their equivalents, the present disclosure is also intended to include these modifications and variations.

What is claimed is:

1. A display apparatus, comprising:
a flexible substrate;
a flexible display module on the flexible substrate; wherein the flexible display module is provided with a first non-bending area, a second non-bending area, and a bending area between the first non-bending area and the second non-bending area;
a flexible fingerprint recognition element between the flexible substrate and the flexible display module; wherein the flexible fingerprint recognition element comprises a first flexible fingerprint recognition element and a second flexible fingerprint recognition element which are mutually independent, the first flexible fingerprint recognition element corresponds to the first non-bending area, the second flexible fingerprint recognition element corresponds to the second non-bending area, and a non-fingerprint recognition area corresponding to the bending area is provided between the first flexible fingerprint recognition element and the second flexible fingerprint recognition element; and
a flexible collimation structure between the flexible fingerprint recognition element and the flexible display module, wherein the flexible collimation structure is configured to make light rays form collimation light rays to enter the flexible fingerprint recognition element.

2. The display apparatus according to claim 1, wherein the non-fingerprint recognition area is not provided with a pattern of a fingerprint recognition element.

3. The display apparatus according to claim 1, wherein the first flexible fingerprint recognition element comprises: an array of first thin film transistors between the flexible substrate and the flexible display module, and an array of first light sensing devices connected with the array of first thin film transistors; the second flexible fingerprint recognition element comprises: an array of second thin film transistors between the flexible substrate and the flexible display module, and an array of second light sensing devices connected with the array of second thin film transistors; and
both the first light sensing devices and the second light sensing devices are configured to convert a light signal carrying fingerprint information to an electric signal, and both the first thin film transistors and the second thin film transistors are configured to output the corresponding electric signal to a processing circuit for fingerprint recognition.

4. The display apparatus according to claim 3, further comprising: a first gate driving circuit, a second gate driving circuit, a first source driving circuit and a second source driving circuit, wherein
the first gate driving circuit is electrically connected with gates of the first thin film transistors, the first source driving circuit is electrically connected with sources of the first thin film transistors, and drains of the respective first thin film transistors are electrically connected with the respective first light sensing devices; and
the second gate driving circuit is electrically connected with gates of the second thin film transistors, the second source driving circuit is electrically connected with sources of the second thin film transistors, and drains of the respective second thin film transistor are electrically connected with the respective second light sensing devices.

5. The display apparatus according to claim 3, wherein the flexible collimation structure comprises: a light shielding layer between the flexible fingerprint recognition element and the flexible display module, and an array of micro-lenses between the light shielding layer and the flexible display module; and
the light shielding layer is provided with a light shielding portion and a plurality of via holes in the light shielding portion, an orthographic projection of the via holes on the flexible substrate has an overlapped area with an orthographic projection of the light sensing devices on the flexible substrate, and the via holes are covered by the micro-lenses.

6. The display apparatus according to claim 1, wherein an orthographic projection of the flexible collimation structure on the flexible substrate covers an orthographic projection of the bending area, the first non-bending area and the second non-bending area on the flexible substrate.

7. The display apparatus according to claim 1, further comprising an infrared light filter layer between the flexible fingerprint recognition element and the flexible collimation structure, wherein the infrared light filter layer is configured to prevent infrared light from entering the flexible fingerprint recognition element.

8. The display apparatus according to claim 7, wherein an orthographic projection of the infrared light filter layer on the flexible substrate covers an orthographic projection of the bending area, the first non-bending area and the second non-bending area on the flexible substrate.

9. The display apparatus according to claim 1, further comprising a blocking layer between the flexible substrate and the flexible fingerprint recognition element, wherein the blocking layer is made of SiNx or a combination of SiNx and SiO₂.

10. The display apparatus according to claim 1, wherein the flexible substrate is made of polyimide.

11. The display apparatus according to claim 1, wherein a thickness of the flexible substrate is 15 μm to 30 μm.

12. The display apparatus according to claim 1, wherein the flexible collimation structure and the flexible display module are fitted with each other by an optical clear adhesive.

13. The display apparatus according to claim 1, further comprising: a cover plate which is on a side, facing away from the flexible substrate, of the flexible display module.

14. The display apparatus according to claim 13, wherein the cover plate is a flexible cover plate.
